(19) United States
(12) Patent Application Publication
(10) Pub. No.: US 2011/0260730 A1
(43) Pub. Date: Oct. 27, 2011

(54) Switchable front-end measurement unit for towed marine electromagnetic survey cables

(76) Inventors: Gustav Göran Mattias Südow, Vallingby (SE); Ulf Peter Lindqvist, Segeltorp (SE); Andras Robert Juhasz, Hagersten (SE)

(21) Appl. No.: 12/799,528

(22) Filed: Apr. 27, 2010

(51) Int. Cl. G01R 33/44

(52) U.S. Cl. 324/365

(57) ABSTRACT

A marine electromagnetic streamer includes a plurality of electrodes disposed along a longitudinal dimension of the streamer. At least one signal processing module is disposed at a selected position along the streamer. A multipole switch associated with the at least one module is electrically coupled between a signal input of the signal processing module and selected pairs of the electrodes. The switch is configured to enable the selected pairs coupled to the switch such that selection thereof results in at least one of selected electrode spacing and selected electrode offset from an electromagnetic energy source.

### CROSS-REFERENCE TO RELATED APPLICATIONS

Not applicable.

### STATEMENT REGARDING FEDERALLY SPONSORED RESEARCH OR DEVELOPMENT

Not applicable.

### BACKGROUND OF THE INVENTION

1. Field of the Invention

The invention relates generally to the field of marine electromagnetic survey methods and apparatus. More specifically, the invention relates to electromagnetic survey streamers that can be electrically reconfigured to have selectable receiver spacing and offset.

2. Background Art

Marine controlled source electromagnetic (CSEM) surveying is a geophysical surveying technique that uses electromagnetic (EM) energy to identify possible hydrocarbon bearing rock formations below the bottom of a body of water such as a lake or the ocean. In a typical marine CSEM survey, an EM source and a number of EM sensors are located at or near the bottom of a body of water. The EM source is typically towed over an area of interest in the Earth's subsurface, and the sensors are disposed on the water bottom over the area of interest to obtain signals related to the distribution of electrical resistivity in the subsurface area of interest. Such surveying is performed for a range of EM source and EM sensor positions. The EM source emits either or both a time varying electric field and a time varying magnetic field, which propagate outwardly into the overlying seawater and downwardly into the formations below the water bottom. The sensors most commonly used detect and record the induced electric field at or near the water bottom. The time varying EM field may be induced by passing electric current through an antenna. The electric current may be continuous wave and have one or more discrete frequencies. Such current passing through an antenna is used for what is referred to as “frequency domain CSEM” surveying. It is also known in the art to apply direct current to an antenna, and produce transient EM fields by switching the current. Such switching may include, for example, switching on, switching off, inverting polarity, and inverting polarity after a switch-on or switch-off event. Such switching may be sequenced in time, for example, equally time spaced, or in a time series known as a “pseudo random binary sequence.” Such switched current is used to conduct what is referred to as a “transient CSEM” survey.

The EM energy is rapidly attenuated in the conductive seawater, but in less conductive subsurface formations is attenuated less and propagates more efficiently. If the frequency of the EM energy is low enough, the EM energy can propagate deep into the subsurface formations. Energy “leaks” from resistive subsurface layers, e.g., a hydrocarbon-filled reservoir, back to the water bottom. When the source-sensor spacing (“offset”) is comparable to or greater than the depth of burial of the resistive layer (the depth below the water bottom) the energy reflected from the resistive layer will dominate over the transmitted energy. CSEM surveying uses the large resistivity contrast between highly resistive hydrocarbons and conductive aqueous saline fluids disposed in permeable subsurface formations to assist in identifying hydrocarbon reservoirs in the subsurface.

The sensor layout in a typical electromagnetic streamer system typically consists of spaced apart electrode pairs distributed along the length of the streamer. The electrode separation normally increase as a function of offset to the electromagnetic source, thus the hardware configuration is changed based on the absolute position at which the measurement node is located. The increment is a necessity as the signal to noise ratio degrades with increasing offset, and the only way to improve this ratio is by separating the electrodes. However, from a production point of view, this adds complexity to the system design and increases the number of spares, as each unique hardware configuration needs redundancy. An improvement of this rather crude design is to increase the number of channels at each node to cover more electrode configurations. The drawback of this implementation is however that a configuration with N possible pair combinations requires N channels at each measurement node.

There continues to be a need for improved configurations of electromagnetic sensor streamer that simplify construction and minimize production of unique parts for cost control.

### SUMMARY OF THE INVENTION

A marine electromagnetic streamer according to one aspect of the invention includes a plurality of electrodes disposed along a longitudinal dimension of the streamer. At least one signal processing module is disposed at a selected position along the streamer. A multipole switch associated with the at least one module is electrically coupled between a signal input of the signal processing module and selected pairs of the electrodes. The switch is configured to enable selection of at least one of selected electrode spacing and selected electrode offset from an electromagnetic energy source.

A marine electromagnetic survey system according to another aspect of the invention includes a survey vessel and at least one sensor streamer towed by the survey vessel. The sensor streamer includes a plurality of electrodes disposed along a longitudinal dimension of the sensor streamer, at least one signal processing module disposed at a selected position along the sensor streamer, and a multipole switch associated with the at least one signal processing module electrically coupled between a signal input of the signal processing module and selected pairs of the electrodes. The switch is configured to enable selection of at least one of selected electrode spacing and selected electrode offset from an electromagnetic energy source. A signal communication line is operably coupled between an output each signal processing module and the survey vessel.

A method for electromagnetic surveying in a body of water according to another aspect of the invention includes imparting an electromagnetic field into the water at a selected position. A plurality of electrodes is disposed at selected positions in the water. Pairs of the electrodes are selectively connected across an input of a signal processing device so as to vary at least one of an offset and an electrode spacing between successive pairs.

Other aspects and advantages of the invention will be apparent from the following description and the appended claims.

### BRIEF DESCRIPTION OF THE DRAWINGS

FIG. 1 is a perspective view of an electromagnetic signal acquisition system that may be used in accordance with the present invention.

FIG. 2 shows more detail of one example of a sensor module in the cable system of FIG. 1.

FIG. 3 shows more detail of example measurement and communication circuitry of the sensor module shown in FIG. 2.

### DETAILED DESCRIPTION

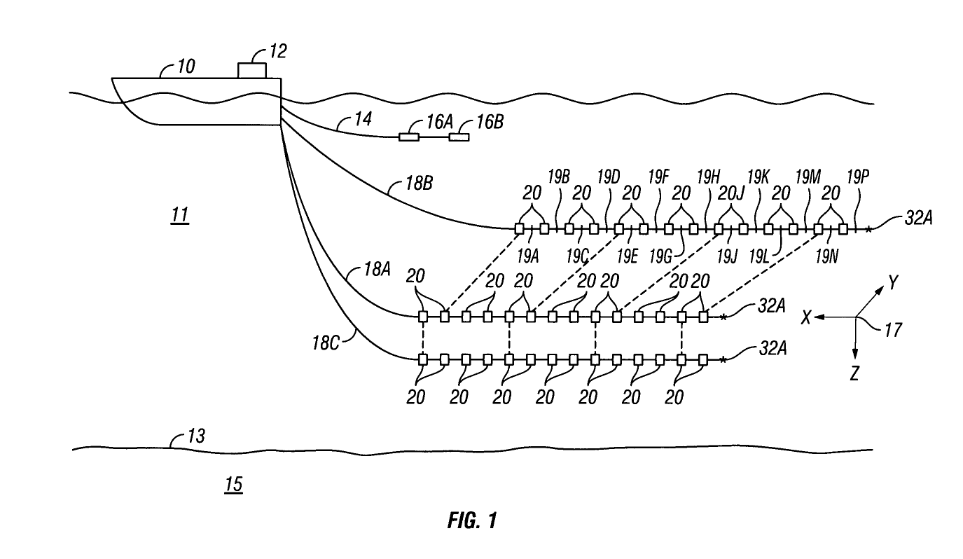

FIG. 1 is a perspective view of an electromagnetic signal acquisition system that may be used in accordance with the present invention. A survey vessel 10 moves along the surface of a body of water 11 such as a lake or the ocean. The survey vessel 10 may include thereon equipment shown at 12 and referred to for convenience as a “recording system.” The recording system 12 may include devices (none shown separately in FIG. 1) for navigation of the vessel 10, for imparting electric current to an electromagnetic transmitter (explained below) and for detecting and recoding signals generated by each of a plurality of electromagnetic sensors (explained below) disposed at spaced apart positions one or more sensor streamers, which may be towed by the survey vessel 10 or by another vessel.

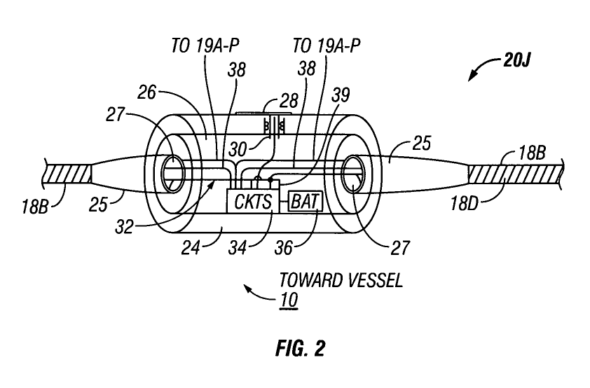

The transmitter in the present example may be an armored, insulated electrical cable 14 having thereon spaced apart electrodes 16A, 16B. The cable 14 and electrodes 16A, 16B may be towed by the survey vessel 10 or another vessel. At selected times, the recording system 12 will impart electric current across the electrodes 16A, 16B. The electrical current may be, for example, continuous wave low frequency (e.g., about 0.01 to about 1 Hz) alternating current at one or more discrete frequencies for frequency domain electromagnetic surveying, or some form of switched direct current (e.g. switched on, switched off, reversed polarity or a series of switching events such as a pseudo-random binary sequence) for time domain electromagnetic surveying. An electromagnetic field induced by the current flowing across the electrodes 16A, 16B travels through the water, into rock formations 15 below the water bottom 13 and is detected by electromagnetic sensors disposed in or near sensor modules 20 on the one or more sensor cables. In the present example there may be a first, second and third streamer cable 18A, 18B, 18C, respectively. Each streamer cable 18A, 18B, 18C may in some implementations include an electrode 32A at the aft end thereof (furthest from the vessel 10) exposed to the water 11. The purpose of the aft electrode(s) 32A will be further explained with reference to FIG. 2.

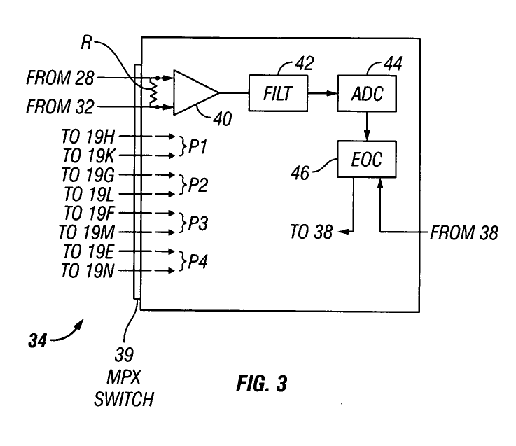

The streamer cable shown at 18B may include a plurality of spaced apart electrodes 19A through 19P disposed on an exterior surface of the cable 18B. The electrodes 19A through 19P are configurable to be selectively electrically connected to one or more signal processing devices inside one or more of the sensor modules 20. As will be explained further below with reference to FIGS. 2 and 3, each sensor module 20 may have circuitry proximate thereto for measuring voltage imparted between an electrode (28 in FIG. 2) disposed on the outer surface sensor module 20 and a reference potential line (32 in FIG. 2) in response to the electromagnetic field imparted into the subsurface by the transmitter. Alternatively, as will be explained with reference to FIG. 3, some of the electrodes 19A to 19P may be selectively connected to signal processing circuits in one or more of the modules (e.g., 20J) by including a switching circuit (FIG. 3) to connect different pairs of the electrodes 19A-19P as input to voltage measuring circuits in the module 20J.

It should also be understood that while the present example transmitter, known as a horizontal electric dipole, uses a pair of electrodes spaced apart in the horizontal plane, other types of transmitters that may be used with the present invention include vertical electric dipoles (electrodes spaced apart in the vertical plane) or vertical or horizontal magnetic dipoles such as wire coils or loops having magnetic moment along the vertical and/or horizontal directions.

FIG. 1 also shows a coordinate system 17 used in the present description and to illustrate that the second streamer 18B may be displaced from the first streamer 18A in the horizontal plane or Y direction, and the third streamer 18C may be displaced from the first streamer 18A in the vertical plane or Z direction. The sensor modules 20 on all three streamer cables 18A, 18B, 18C may be positioned at corresponding longitudinal distances from the vessel 10 to simplify calculation of certain measurements.

As will be explained further, the second and third streamers 18A, 18C may be used to obtain electric field measurements in the Y and Z directions, called the “cross-line” directions, by measuring voltages impressed across corresponding electrodes (i.e., longitudinally about the same distance from the survey vessel 10) on different streamers, as well as the so-called “in-line” direction across pairs of electrodes spaced apart in the X direction as explained above. However, the use of additional streamers 18A and 18C to obtain cross line measurements is not necessary in order to make and use the invention. The foregoing example is provided to show that using the additional streamers to make cross line measurements is a possible feature in some implementations. Each of the other streamers 18A and 18C can be configured with electrodes 19A-19P as explained above and with switching circuitry as explained below with reference to FIGS. 2 and 3. Thus, a system as described herein may be selectively configured to operate in 2D or 3D cross line acquisition more, or may be configured to variable sensor spacing/variable offset between transmitters and sensors. Each such change in configuration may be performed by operating switches located in one or more of the sensor modules, and need not require substituting different streamer components. Still further, only one sensor streamer, configured as shown at 18B in FIG. 1 and more fully explained with reference to FIGS. 2 and 3 may be used in other examples. In another example, a plurality of streamers spaced apart in the Y-direction and configured as shown at 18B may be used in parallel to increase the area of the subsurface surveyed with any pass of the survey vessel 10 even if cross-line measurements are not made or used.

One example of a sensor streamer cable 18B and one of the sensor modules 20J including reconfiguration capability shown in more detail in FIG. 2. The streamer cable 18B may include on its exterior helically wound, electrically conductive armor wires 18D, such as may be made from stainless steel or other high strength, corrosion resistant, electrically conductive material. In one example, to be explained in more detail below, the streamer cable 18B may include one or more insulated electrical conductors and one or more optical fibers disposed inside the armor wires 18D. Using an externally armored cable as shown in FIG. 2 may have the advantages of high axial strength of and high resistance to abrasion.

The streamer cable 18B in the present example may be divided into segments, each of which terminates with a combination mechanical/electrical/optical connector 25 (“cable connector”) coupled to the longitudinal ends of each cable segment. The cable connector 25 may be any type known in the art to make electrical and/or optical connection, and to transfer axial loading to a mating connector 27. In the present example such mating connector 27 can be mounted in each longitudinal end of one of the sensor modules 20. The connectors 25, 27 resist entry of fluid under pressure when the connectors 25, 27 are coupled to each other.

The sensor module housing 24 is preferably pressure resistant and defines a sealed interior chamber 26 therein. The housing 24 may be made from electrically non-conductive, high strength material such as glass fiber reinforced plastic, and should have a wall thickness selected to resist crushing at the maximum expected hydrostatic pressure expected to be exerted on the housing 24. The mating connectors 27 may be arranged in the longitudinal ends of the housing 24 as shown in FIG. 2 such that axial loading along the streamer cable 18B is transferred through the sensor module housing 24 by the coupled cable connectors 25 and mating connectors 27. Thus, the streamer cable 18B may be assembled from a plurality of connector-terminated segments each coupled to a corresponding mating connector on a sensor module housing 24 or other connector. Alternatively, the streamer cable 18B may include armor wires 18D extending substantially continuously from end to end, and the sensor modules 20 may be affixed to the exterior of the armor wires 18D.

An electromagnetic sensor, which may be a first electrode 28, is disposed on the outer surface of the housing 24, and may be made, for example, from lead, gold, graphite or other corrosion resistant, electrically conductive, low electrode potential material. Electrical connection between the first electrode 28 and measuring circuits 34 (explained in more detail with reference to FIG. 3) disposed inside the chamber 26 in the housing 24 may be made through a pressure sealed, electrical feed through bulkhead 30 disposed through the wall of the housing 24 and exposed at one end to the interior of the chamber 26. One such feed through bulkhead is sold under model designation BMS by Kemlon Products, 1424 N. Main Street, Pearland, Tex. 77581.

The measuring circuits 34 may be powered by a battery 36 disposed inside the chamber 26 in the housing 24. Battery power may be preferable to supplying power from the recording system (12 in FIG. 1) over insulated electrical conductors in the streamer cable 18B so as to reduce the possibility of any electromagnetic fields resulting from current flowing along the cable 18B from interfering with the electromagnetic survey measurements made in the various sensor modules 20. There may be a multipolar electronic or combined microelectronic mechanical system (MEMS) switch 39 disposed between output of the electrodes and a signal input to the processing circuits 34. The switch 39 will be further explained with reference to FIG. 3.

The streamer cable 18B may include one or more optical fibers 38 for conducting command signals, such as from the recording system (12 in FIG. 1) to the circuits 34 in the various sensor modules 20, and for conducting signal telemetry from the modules 20 to the recording system (12 in FIG. 1) or to a separate data storage device (not shown). An insulated electrical conductor 32 forming part of the cable (18B in FIG. 2) may pass through the chamber 26 in the housing 24 such that electrical continuity in such conductor 32 is maintained along substantially the entire length of the cable 18.

Optical telemetry may be preferable to electrical telemetry for the same reason as using batteries for powering the circuits 34, namely, to reduce the incidence of electromagnetic fields caused by electrical current moving along the cable 18B. The insulated electrical conductor 32 in the present example serves as a common potential reference line between all of the sensor modules 20.

The insulated conductor 32 may be electrically in contact with the water (11 in FIG. 1) at the aft end of the streamer cable 18B by using an electrode (32A in FIG. 1) at the aft end of the streamer cable 18B. If the distance between the aft end of the streamer cable 18B and the transmitter (16A, 16B in FIG. 1) is sufficiently large, the voltage at the electrode (32A in FIG. 1) and thus along the entire electrical conductor 32 is substantially zero notwithstanding the electromagnetic field induced by the transmitter. The same cable configuration as explained herein with reference to FIG. 2 and further explained with reference to FIG. 3 may be used for all three streamer cables (18A, 18B, 18C in FIG. 1), and in each case the conductor 32 will represent a substantially zero voltage reference line along the entire length of each streamer cable.

One example of the signal processing circuits 34 is shown in more detail in FIG. 3. The circuits 34 may include a resistor R electrically coupled between the measuring electrode (28 in FIG. 2) and the insulated conductor 32, which as explained above serves as a common reference. The resistor R is also electrically connected across the input terminals of a preamplifier 40. Thus, voltage drop across the resistor R resulting from voltage difference between a fixed potential reference (conductor 32) and the measuring electrode (28 in FIG. 2) will be input to the preamplifier 40. Such voltage drop will be related to magnitude of the electric field gradient existing where the measuring electrode (28 in FIG. 2) is located at any point in time.

Output of the preamplifier 40 may be passed through an analog filter 42 before being digitized in an analog to digital converter (ADC) 44. Alternatively, the preamplifier 40 output may be directly digitized and the output of the ADC 44 can be digitally filtered. Output of the ADC 44, whether digitally filtered or not, may be conducted to an electrical to optical signal converter (EOC) 46. Output of the EOC 46 may be applied to the one or more optical fibers (38 in FIG. 2) in the cable (18B in FIG. 2) such that optical signals representative of the voltage measured by each measuring electrode (28 in FIG. 2) with respect to the reference conductor (32 in FIG. 2) may be communicated to the recording system (12 in FIG. 1) or to a data storage unit. The type of optical or other signal telemetry used in any implementation is a matter of discretion for the system designer and is not intended to limit the scope of the invention.

The example circuits in FIG. 3 may, as earlier explained, enable selective connection of various pairs of the electrodes (19A-19P) across the inputs of the preamplifier by using a multiplexer or mechanically implemented multipole switch 39. The switch 39 may also be implemented as a MEMS device as explained above. The selective switching of various electrode pairs shown in FIG. 3 provides as a first selection possibility the measurement of voltage between the electrode on the housing 28 and the reference electrode 32. In a second example selection, electrodes 19H and 19K (in FIG. 1) are coupled across the inputs of the preamplifier 40. The foregoing two electrodes are longitudinally relatively close to the module (20J) and so provide relatively short spacing between the electrodes. In the event longer electrode spacing becomes advisable, for example as a result of long offset between the transmitter (16A, 16B in FIG. 1) and the particular electrode pair, more widely spaced apart electrodes may be coupled across the preamplifier 40 input. For example, the switch 39 in its last position may couple electrodes 19E and 19N across the input of the preamplifier 40, thus providing a relatively large configuration.

Although the foregoing example (FIG. 1) shows one electrode between successive modules 20 connecting adjacent streamer segments, it will be appreciated by those skilled in the art that a single segment could be made with the module 20 centrally located and a plurality of electrodes disposed at successively larger distances from the module 20 in each segment. Thus each segment could be individually optimized for the intended use; or could be switched to make two or three dimensional measurements including in the two cross line directions as shown in FIG. 1. It is also possible to select for interconnection across the input terminals of any of the sensor module preamplifiers any two of the electrodes 19A-19P and/or 28, 32, with suitable lead through wires made available for the electrodes.

Embodiments of a streamer cable and sensor module therein according to the various aspects of the invention may enable reconfiguration of one or more electromagnetic sensor streamers to have increased offset and/or increased sensor spacing

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

What is claimed is:

1. A marine electromagnetic streamer, comprising:
a plurality of electrodes disposed along a longitudinal dimension of the streamer;
at least one signal processing module disposed at a selected position along the streamer;
a multipole switch associated with the at least one module, electrically coupled between a signal input of the signal processing module and selected pairs of the electrodes, and configured to enable selection of at least one of electrode spacing and electrode offset from an electromagnetic energy source.

2. The streamer of claim 1 further comprising a plurality of signal processing modules disposed at selected longitudinal positions along the streamer, each module having an associated multipole switch electrically connected between selected pairs of electrodes.

3. The streamer of claim 2 wherein each signal processing module comprises an electrode disposed on an exterior of the signal processing module, and one multipole switch selection connects the signal input of such signal processing module between the module exterior electrode and a common potential reference line extending the length of the streamer, the reference line including an electrode in contact with a body of water at an aft longitudinal end of the streamer.

4. A marine electromagnetic survey system, comprising:
a survey vessel;
at least one sensor streamer towed by the survey vessel, the sensor streamer comprising:
a plurality of electrodes disposed along a longitudinal dimension of the sensor streamer;
at least one signal processing module disposed at a selected position along the sensor streamer; and
a multipole switch associated with the at least one signal processing module, electrically coupled between a signal input of the signal processing module and selected pairs of the electrodes, and configured to enable selection of at least one of electrode spacing and electrode offset from an electromagnetic energy source; and
a signal communication line operably coupled between an output of each signal processing module and the survey vessel.

5. The system of claim 4, further comprising
at least one electromagnetic transmitter towed by the vessel in a body of water; and
a source of electric current selectively actuable to pass electric current through the at least one transmitter.

6. The system of claim 4 further comprising a plurality of signal processing modules disposed at selected longitudinal positions along the sensor streamer, each signal processing module having an associated multipole switch electrically connected between selected pairs of electrodes.

7. The system of claim 4 wherein each signal processing module comprises an electrode disposed on an exterior of the signal processing module, and one multipole switch selection connects the signal input of such signal processing module between the module exterior electrode and a common potential reference line extending the length of the sensor streamer, the reference line including an electrode in contact with a body of water at an aft longitudinal end of the streamer.

8. The system of claim 5 further comprising:
a plurality of sensor streamers towed by the vessel, each sensor streamer comprising:
a plurality of electrodes disposed along a longitudinal dimension of the sensor streamer;
at least one signal processing module disposed at a selected position along the sensor streamer; and
a multipole switch associated with the at least one signal processing module, electrically coupled between a signal input of the signal processing module and selected pairs of the electrodes, and configured to enable selection of at least one of electrode spacing and electrode offset from the transmitter; and
a signal communication line operably coupled between an output of each signal processing module and the survey vessel.

9. The system of claim 8 wherein the switch in each signal processing module includes a setting that connects an electrode disposed proximate the signal processing module and a common potential reference line extending the length of each streamer, the reference line including an electrode in contact with a body of water at an aft longitudinal end of the respective streamer.

10. A method for electromagnetic surveying in a body of water, comprising:
imparting an electromagnetic field into the water at a selected position;
disposing a plurality of electrodes at selected positions in the water;
selectively connecting pairs of the electrodes across an input of a signal processing device, the selectively connecting including selecting the pairs so as to vary at least one of an offset and an electrode spacing between successive pairs.
